(19) United States
(12) Patent Application Publication
(10) Pub. No.: US 2021/0336415 A1
(43) Pub. Date: Oct. 28, 2021

(54) NON-REFRIGERATED TUNABLE SEMICONDUCTOR LASER BASED ON MULTI-WAVELENGTH ARRAY AND PREPARATION METHOD

(71) Applicant: Nanjing Huafei Optoelectronics Technology Co., Ltd., Nanjing (CN)

(72) Inventors: Xiangfei CHEN, Nanjing (CN); Rulei XIAO, Nanjing (CN); Jun LU, Nanjing (CN); Tao FANG, Nanjing (CN); Yuechun SHI, Nanjing (CN)

(73) Assignee: Nanjing Huafei Optoelectronics Technology Co., Ltd., Nanjing (CN)

(21) Appl. No.: 17/235,955

(22) Filed: Apr. 21, 2021

(30) Foreign Application Priority Data
Apr. 22, 2020 (CN) 202010320863.2

(51) Int. Cl. H01S 5/0683; H01S 5/40; H01S 5/068; H01S 5/12; H01S 5/22; H01S 5/06; H01S 5/02355

(52) U.S. Cl. CPC H01S 5/0683; H01S 5/4087; H01S 5/06804; H01S 5/4012; H01S 5/22; H01S 5/0617; H01S 5/02355; H01S 5/12

(57) ABSTRACT

A non-refrigerated tunable semiconductor laser based on a multi-wavelength array includes a thermistor, a tunable laser array, a multiplexing structure, an optical amplifier, an optical splitter, an optical detector, and a main controller. The tunable laser array include a plurality of laser units with different wavelengths, and the tunable laser array is connected to the optical splitter and the main controller through the multiplexing structure and the optical amplifier in sequence. When the laser is influenced by the external environment temperature, the value of the influence caused by the external environment temperature is calculated, and drive currents of the tunable laser array and the optical amplifier are adjusted and controlled respectively according to the calculation result, so as to achieve the purpose that parameters of the final output light are consistent with parameters of the theoretical light.

### CROSS REFERENCE TO THE RELATED APPLICATIONS

This application is based upon and claims priority to Chinese Patent Application No. CN 202010320863.2, filed on Apr. 22, 2020, the entire contents of which are incorporated herein by reference.

### TECHNICAL FIELD

The present invention relates to the technical field of optical communication, and more particularly, to a non-refrigerated tunable semiconductor laser based on a multi-wavelength array and a preparation method thereof.

### BACKGROUND

With the development of Internet technology, the emergence of 5G and artificial intelligence, the continuous increase of network data traffic, the continuous increase of access devices, the virtualization of content and servers, and the rapid growth of cloud services, the prior static network system will face tremendous pressure due to its fixed network lines and difficult adjustment and distribution of traffic. In the future network solution, regardless of the expansion of data capacity or the enhancement of network flexibility, in order to realize dynamically changing the network architecture, a large number of semiconductor lasers with tunable wavelengths are necessarily used in a network equipment. However, at present, the high cost of commercial tunable semiconductor lasers severely limits the promotion of related technologies, and it is thus highly desirable to technically reduce the cost of the tunable semiconductor lasers. In conventional tunable semiconductor laser devices, the power consumption of a thermal electronic cooler (TEC) is one of the main power consumption sources of the laser devices and is also one of the main cost sources of low-cost lasers. The omission of the cooler can dramatically reduce the cost of an optical module, the power consumption, and the volume. Therefore, in terms of cost and energy consumption, it is of great importance to develop the non-refrigerated wavelength division multiplex (WDM) device technology. Besides, due to using TEC, the laser devices basically all need to adopt a sealed package structure, except for the complicated preparation process, the costs of the laser devices are also additionally increased. Therefore, the present invention provides a solution of realizing a non-refrigerated tunable semiconductor laser as a solution of a low-cost semiconductor tunable light source.

### SUMMARY

An objective of the present invention is to provide a non-refrigerated tunable semiconductor laser based on a multi-wavelength array and a preparation method thereof. When the laser is influenced by the external environment temperature, the value of the influence caused by the external environment temperature is calculated, and drive currents of the tunable laser array and the optical amplifier are adjusted and controlled respectively according to the calculation result, so as to achieve the purpose that parameters of the final output light are consistent with parameters of the theoretical light. Since no cooler is used, the overall structure of the laser is dramatically reduced, the preparation process is further simplified, and even the sealed package structure may not be used, thereby greatly reducing the cost of the laser device.

In order to achieve the above objective, with reference to FIG. 1, the present invention further provides a non-refrigerated tunable semiconductor laser based on a multi-wavelength array. The semiconductor laser includes a thermistor, a tunable laser array, a multiplexing structure, an optical amplifier, an optical splitter, an optical detector, and a main controller.

The tunable laser array includes a plurality of laser units with different wavelengths, and is connected to the optical splitter and the main controller through the multiplexing structure and the optical amplifier in sequence. One of the laser units is driven to emit a laser beam with a corresponding wavelength according to a control instruction of the main controller, and the laser beam is amplified by the optical amplifier and then enters the optical splitter. The optical splitter is provided with two output ends, wherein one output end is set as a light outputting end, and the other output end is connected to the main controller through the optical detector to constitute a feedback loop to feed back characteristics of a wavelength and a power of an actual output light to the main controller in real time.

The thermistor is connected to the main controller to detect an external environment temperature in real time and feed back a detection result to the main controller.

The main controller calculates a corrected wavelength value after a compensation for a wavelength drift in conjunction with a set theoretical wavelength and the external environment temperature detected in real time, and initially adjusts drive current of the tunable laser array to drive a laser unit with a wavelength of being closest to the corrected wavelength value to emit the laser beam. Then, according to the fed-back characteristics of the wavelength and the power of the actual output light, the main controller fine-tunes the drive current of the tunable laser array and drive current of the optical amplifier in conjunction with the set theoretical wavelength and a theoretical power to enable the actual output light to satisfy requirements of the theoretical wavelength and the theoretical power.

In a further embodiment, the semiconductor laser further includes a heat sink substrate, and the heat sink substrate is configured as a carrier of the thermistor, the tunable laser array, the multiplexing structure and the optical amplifier.

In a further embodiment, the multiplexing structure includes a passive multiplexing structure and an active multiplexing structure.

The passive multiplexing structure includes a multimode interferometer structure, a cascaded Y-branch waveguide structure or an arrayed waveguide grating structure.

The active multiplexing structure includes a cascaded Y-branch waveguide structure.

In a further embodiment, a maximum wavelength tuning range of the tunable laser array satisfies:

the maximum tuning wavelength range=a theoretical tuning wavelength range+an additional tuning wavelength range.

The additional tuning wavelength range is determined by characteristics of the wavelength drift caused by a variation of the environment temperature.

In a further embodiment, a fixed wavelength interval is disposed between the laser units.

The total number of the laser units of the tunable laser array satisfies:

the total number of the laser units=the maximum tuning wavelength range/the wavelength interval.

In a further embodiment, the laser units are arranged in parallel, in series or in a matrix form.

In a further embodiment, the laser units include a distributed feedback (DFB) laser using a reconstruction-equivalent-chirp technology, and a waveguide structure includes a ridge waveguide type and a buried heterostructure type.

When the waveguide structure is the ridge waveguide type, a deep etching is performed on both sides of a waveguide to confine a light.

When the waveguide structure is the buried heterostructure type, an indium phosphide material is grown and buried on both sides of the waveguide to confine the light.

In a further embodiment, a specific proportion of the optical splitter is determined by an output light intensity and a minimum light intensity required by the optical detector.

Based on the aforementioned non-refrigerated tunable semiconductor laser, the present invention further provides a working method of a non-refrigerated tunable semiconductor laser based on a multi-wavelength array. The working method includes:

S1: collecting the external environment temperature, the characteristics of the wavelength and the power of the actual output light in real time;

S2: calculating a difference between the wavelength of the actual output light and the theoretical wavelength; if the difference is greater than a tunable range of a current laser unit in a working state, going to step S3, otherwise, going to step S4;

S3: calculating the corrected wavelength value after the compensation for the wavelength drift, and initially adjusting the drive current of the tunable laser array to drive the laser unit with the wavelength of being closest to the corrected wavelength value to emit the laser beam;

S4: in conjunction with a difference between a fed-back wavelength value of the actual output light and the theoretical wavelength, using a thermal effect tuning method of the drive current to fine-tune the drive current of the tunable laser array to enable the fed-back wavelength value of the actual output light to be consistent with the theoretical wavelength; and

S5: in conjunction with a fed-back power value of the actual output light and the theoretical power, fine-tuning the drive current of the optical amplifier to enable the fed-back power value of the actual output light to be consistent with the theoretical power.

Based on the aforementioned non-refrigerated tunable semiconductor laser, the present invention further provides a preparation method of a non-refrigerated tunable semiconductor laser based on a multi-wavelength array. The preparation method includes:

S100: preparing the tunable laser array; the tunable laser array is an array-type distributed feedback semiconductor laser chip based on a reconstruction-equivalent-chirp technology, and includes the plurality of laser units with different wavelengths; one of the laser units is driven to emit the laser beam with the corresponding wavelength according to the control instruction of the main controller;

S200: bonding the thermistor and the prepared tunable laser array to a heat sink substrate configured as a carrier by welding or gluing; an angle for suppressing an Fabry-Perot (F-P) cavity effect is formed between a light outputting end face of the tunable laser array and an upper surface of the heat sink substrate;

S300: integrating a passive multiplexing structure at an output end of the tunable laser array through a photonic wire bonding technology, or monolithically integrating an active multiplexing structure at the output end of the tunable laser array through material growth, so as to realize a single-port light outputting function of the tunable laser array;

S400: integrating a semiconductor optical amplifier at an end of the passive multiplexing structure or an end of the active multiplexing structure, and amplifying or attenuating a power of a final output light by changing an input current of the optical amplifier; and

S500: coupling an end of the optical amplifier with an optical fiber by packaging an isolator microlens assembly at the end of the optical amplifier or using the photonic wire bonding technology to enable a laser light emitted by the laser chip to be output through the optical fiber.

Compared with the prior art, the above technical solutions of the present invention have the following obvious advantages.

(1) When the laser is influenced by the external environment temperature, the value of the influence caused by the external environment temperature is calculated, and drive currents of the tunable laser array and the optical amplifier are adjusted and controlled respectively according to the calculation result, so as to achieve the purpose that parameters of the final output light are consistent with parameters of the theoretical light.

(2) Since no cooler is used, the overall structure of the laser is dramatically reduced, the preparation process is further simplified, and even the sealed package structure may not be used, thereby greatly reducing the cost of the laser device.

(3) Unlike the conventional technology that uses the cooler to offset the influence of the external environment temperature, the present invention accepts the influence of any environmental factor including the external environment temperature on the output light, calculates and analyzes the final influence value, and re-selects the laser unit or fine-tune the laser unit and the optical amplifier in conjunction with the analysis result to realize the purpose that the output light is consistent with the theoretical light. Therefore, compared with the prior art, the laser device provided by the present invention has lower power consumption and wider adaptability, its adjusting and controlling object is not limited to such a main influencing factor of the external environment temperature, and the parameter accuracy of the finally realized output light is high.

(4) The thermistor is used to detect the external environment temperature in real time, the influence value is accurately calculated in conjunction with the analysis result of the optical detector on one of the output lights of the optical splitter, thereby realizing accurate control.

(5) The specific proportion of the optical splitter is determined by the output light intensity and the minimum light intensity required by the optical detector, and in some occasions, the optical splitter can also assist in adjusting the actual power of the output light.

(6) The thermistor and the prepared tunable laser array are bonded to the heat sink substrate configured as a carrier by welding or gluing. The passive multiplexing structure is integrated at the output end of the tunable laser array through the photonic wire bonding technology, or the active multiplexing structure is monolithically integrated at the output end of the tunable laser array through material growth. The end of the optical amplifier is coupled with an optical fiber by packaging an isolator microlens assembly at end of the optical amplifier or using the photonic wire bonding technology. The present invention has a small limit on the type of each structural members and can arbitrarily select one of functional members according to the actual situation. Moreover, the preparation process is mature and reliable, the preparation success rate is high, and the preparation cost is low.

It should be understood that all combinations of the foregoing concepts and the additional concepts described in more detail below can be regarded as a part of the inventive subject matter of the present invention as long as such concepts are not contradictory to each other. In addition, all combinations of the claimed subject matters are regarded as a part of the inventive subject matter of the present invention.

The foregoing and other aspects, embodiments and features taught by the present invention can be more fully understood from the following description with reference to the drawings. Other additional aspects of the present invention, such as the features and/or advantages of the exemplary embodiments, will be apparent in the following description, or understood by the implementation of the specific embodiments taught in accordance with the present invention.

### BRIEF DESCRIPTION OF THE DRAWINGS

The drawings are not intended to be drawn in proportion. In the drawings, each identical or nearly identical component shown in each figure may be represented by the same reference number. For clarity, not every component is marked in each figure. Now, embodiments of various aspects of the present invention will be described through examples with reference to the drawings.

FIG. 1 shows a modular schematic diagram of a non-refrigerated tunable semiconductor laser based on a multi-wavelength array according to the present invention.

FIGS. 2A-2H show schematic diagrams of specific structures of multiple examples of the non-refrigerated tunable semiconductor laser based on the multi-wavelength array according to the present invention.

FIG. 3 shows a flow chart of a working method of the non-refrigerated tunable semiconductor laser based on the multi-wavelength array of the present invention.

FIG. 4 shows a flow chart of a preparation method of the non-refrigerated tunable semiconductor laser based on the multi-wavelength array according to the present invention.

FIG. 5 shows a schematic diagram of a tuning range of a tunable laser array according to the present invention.

FIG. 6A shows a schematic diagram of a spectrum of the tunable laser array according to the present invention, and FIG. 6B shows a schematic diagram of a tuned spectrum of the tunable laser array according to the present invention.

FIGS. 7A-7B show schematic diagrams of structures of a laser unit according to the present invention.

### DETAILED DESCRIPTION OF THE EMBODIMENTS

In order to better understand the technical contents of the present invention, specific embodiments are specially listed and explained below with reference to the drawings.

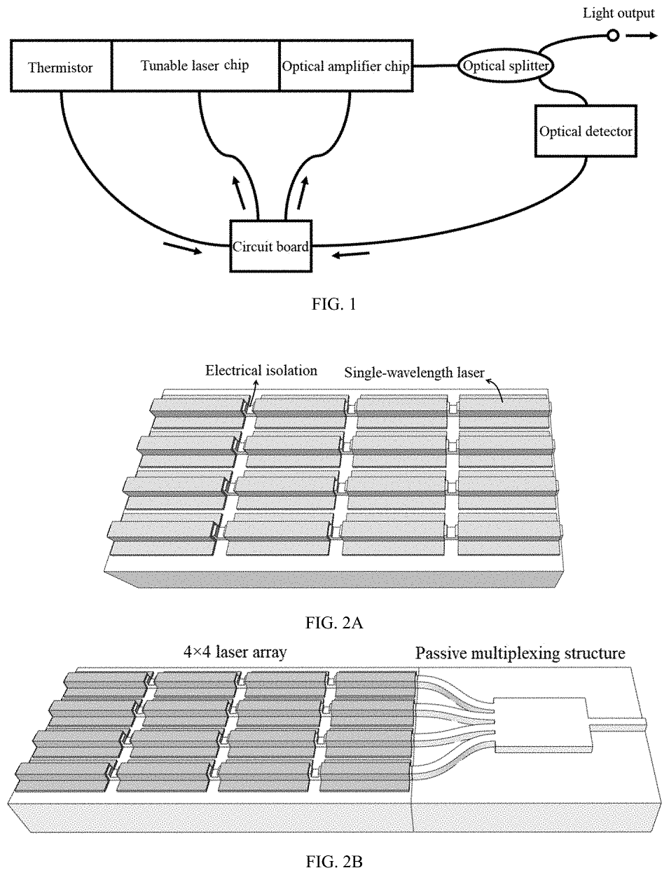

Referring to FIG. 1, the present invention provides a non-refrigerated tunable semiconductor laser based on a multi-wavelength array. The semiconductor laser includes a thermistor, a tunable laser array, a multiplexing structure, an optical amplifier, an optical splitter, an optical detector, and a main controller.

The tunable laser array includes a plurality of laser units with different wavelengths, and is connected to the optical splitter and the main controller through the multiplexing structure and the optical amplifier in sequence. One of the laser units is driven to emit a laser beam with a corresponding wavelength according to a control instruction of the main controller, and the laser beam is amplified by the optical amplifier and then enters the optical splitter. The optical splitter is provided with two output ends, wherein one output end is set as a light outputting end, and the other output end is connected to the main controller through the optical detector to constitute a feedback loop to feed back characteristics of the wavelength and the power of the actual output light to the main controller in real time.

The thermistor is connected to the main controller to detect the external environment temperature in real time and feed back a detection result to the main controller.

The main controller calculates a corrected wavelength value after compensation for wavelength drift in conjunction with a set theoretical wavelength and the external environment temperature detected in real time, and initially adjusts the drive current of the tunable laser array to drive a laser unit with a wavelength of being closest to the corrected wavelength value to emit the laser beam. Then, according to the fed-back characteristics of the wavelength and the power of the actual output light, the main controller fine-tunes the drive current of the tunable laser array and the drive current of the optical amplifier in conjunction with the set theoretical wavelength and a theoretical power to enable the actual output light to satisfy the requirements of the theoretical wavelength and the theoretical power.

Preferably, the semiconductor laser further includes a heat sink substrate, and the heat sink substrate is configured as a carrier of the thermistor, the tunable laser array, the multiplexing structure and the optical amplifier.

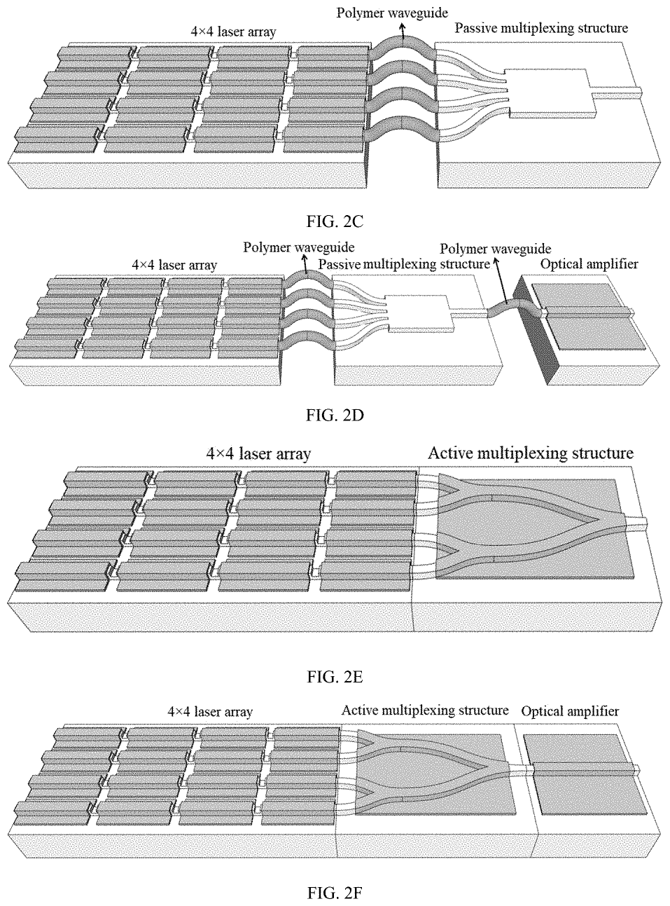

Referring to FIGS. 1 and 2A-2H, the structure of the non-refrigerated tunable semiconductor laser based on the multi-wavelength array of the present invention will be explained in detail below.

(I) Arrangement Manners of the Laser Units

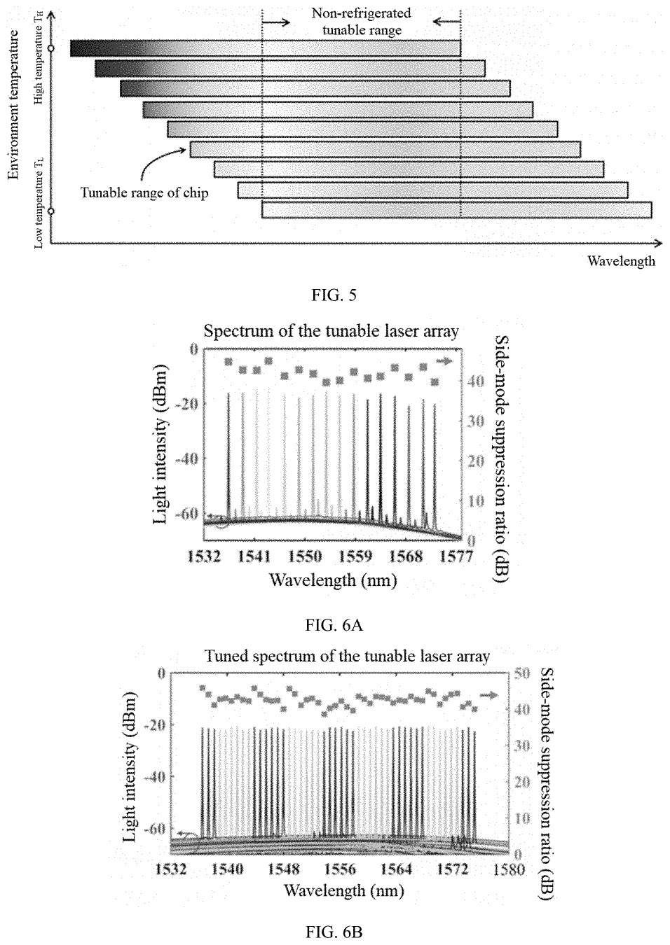

The structure of the tunable semiconductor laser is shown in FIGS. 2A-2H, and its core is a monolithically integrated multi-wavelength DFB laser matrix. A plurality of laser units are contained in the region of the matrix, and all laser unit in the region have different wavelengths, but have an identical wavelength interval Δλ. FIG. 6A shows a schematic diagram of a spectrum of all laser units in the array, and FIG. 6B shows a schematic diagram of a tuned spectrum of all laser units in the array. Emission wavelengths of all laser units can be combined into a comb-shaped spectrum output that can cover a relatively large wavelength range. When used as a tunable laser, only one laser of the multi-wavelength array works every time, and other lasers do not emit to ensure a single-frequency output of the device. In the spatial distribution arrangement, the laser units are arranged in parallel, in series or in a matrix form according to the structural requirements of the laser. FIG. 2A shows one of matrix arrangement forms. The reconstruction-equivalent-chirp technology is used to realize monolithic integration of a plurality of DFB lasers with different wavelengths, in which different lasers are arranged in a matrix form of M×N, and M and N are 1, 2, 3, . . . . Along the x direction in the figure, the difference between the wavelengths of the connected laser units is Δλ. Along the y direction in the figure, the laser units in an identical row share a waveguide structure, and the difference between the wavelengths of the adjacent laser units is M*Δλ. At the light outputting end, the tunable laser array, through a multiplexing structure that is formed by directly combining the bent waveguides, guides the lights emitted from different positions in the space to a light outputting port to be output. An epitaxial structure of the multiplexer part (multiplexing structure) is completely the same as that of the laser, and in the working, the external current is required to enable the epitaxial structure of the multiplexer to work in a transparent or amplified state. Therefore, the epitaxial structure of the multiplexer has functions of the multiplexer and the amplifier simultaneously. The final light outputting end face of the laser needs to be inclined at a certain angle to suppress the F-P cavity effect. The laser includes a structure of an integrated semiconductor optical amplifier (SOA), and the structure is arranged at the light outputting end of the device. The function of the integrated SOA can be directly realized by using an active multiplexer, and can also be realized by being separate from the active multiplexer and separately arranging a segment of an active waveguide structure.

(II) Structure of the Laser Unit

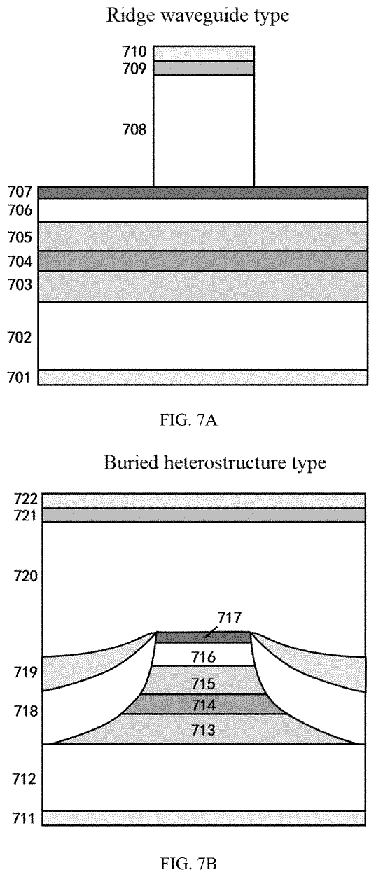

A typical structure of the laser unit is shown in FIG. 7A, and is described in detail as follows. The laser unit is a DFB laser using the reconstruction-equivalent-chirp technology, and the waveguide structure of the laser may be a ridge waveguide type or a buried heterostructure type. The laser is made of indium phosphide and InGaAsP and InGaAlAs quaternary compound semiconductor materials. When the laser employs the structure of the ridge waveguide type, an epitaxial growth structure of the device is shown in FIG. 7A. Specifically, 702 represents a substrate layer of the laser, which is a basic support for growing the main structure of the entire laser. 703 represents a unilateral lower confinement layer, which is a low refractive index epitaxial layer for performing an optical confinement. 704 represents an active layer, which is a double heterostructure or multilayer quantum well structure formed by intrinsic semiconductor materials to convert electrons into photons. 705 represents an upper confinement layer, which has the same function as the lower confinement layer but is made of the p-type doped material. 707 represents a grating layer, on which a DFB grating designed using the reconstruction-equivalent-chirp technology is made to select the lasing wavelength of the laser unit. 708 represents a ridge waveguide layer, and the ridge waveguide structure is made on the present layer by photoetching. 709 represents an ohmic contact layer, which is made of heavily doped InGaAs and is used to form an ohmic contact between a semiconductor material and a metal electrode to reduce resistance. 701 and 710 are metal electrodes, which are used to supply power to the laser.

The device may also employ the waveguide structure of the buried heterostructure type. In this case, the specific structure of the device is shown in FIG. 7B, wherein 712, 713, 714, 715, 716 and 717 represent the same as the corresponding respective layers in the device with the ridge waveguide structure. The waveguide of the BH structure first needs to undergo a deep etching to remove unnecessary parts of the p-type waveguide layer (716), the grating layer 717 and the active layer 714, and the above respective layers only retain the region under the waveguide. Then, the waveguide of the BH structure undergoes a heteroepitaxial growth, and the etched ridge structure is buried again by using the p-type material 718 and the n-type material 719 with different energy gaps to form a BH buried waveguide structure.

(III) The Wavelength Characteristics and Working Principle of the Laser Unit

Preferably, a fixed wavelength interval is disposed between the lasers to facilitate the tuning and controlling, and meanwhile, it is only necessary to adjust the number of laser units to complete the temperature adaptability requirement when the external environment temperature varies. This is determined by the temperature compensation principle of the laser. Unlike the conventional technology that uses the cooler to offset the influence of the external environment temperature, the present invention accepts the influence of any environmental factor including the external environment temperature on the output light and uses an additional wavelength tuning range to compensate for the wavelength drift of the laser caused by the variation of the environment temperature. For example, for an application requirement for wavelength tuning of a communication C-band about 35 nm, which requires a temperature variation of −20° C. to 70° C. to realize non-refrigerated working, the laser itself needs to consider compensating for the wavelength drift caused by the variation of the environment temperatures of the high and low temperature about 90° C. when being designed. Therefore, the wavelength tuning range of the laser needs to be greater than (35+9) nm=44 nm. If the array is designed to have an interval of 2 nm, that is, each laser unit covers a continuous wavelength tuning range about 2 nm, then the tunable laser requires a laser array with at least 22 wavelengths to cover the tuning range of 44 nm. Other situations are similar, and the specific number of laser units with different wavelengths will be designed as needed.

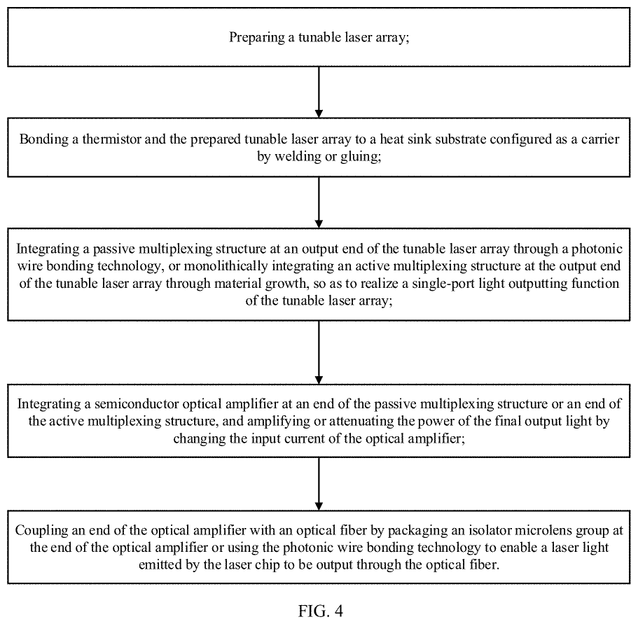

As shown in FIG. 5, the number of lasers integrated in the device is determined jointly by requirements of a non-refrigerated working temperature range and the wavelength tuning range. The wavelength tuning range that the laser can actually achieve is greater than the tuning range required by the application. The additional tuning range is used to compensate for the wavelength drift caused by the temperature variation.

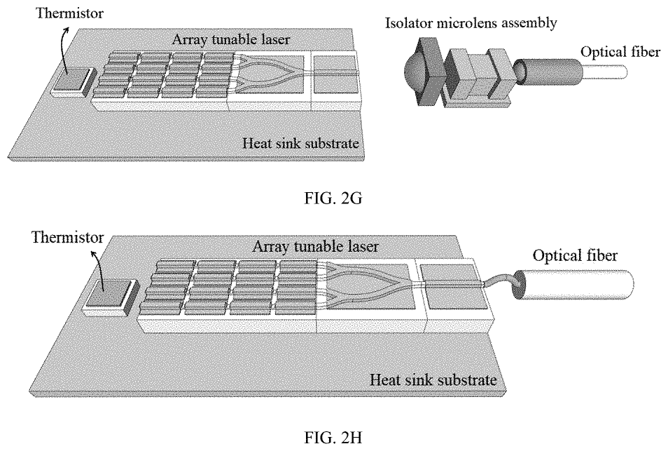

When the laser works, stability of the output wavelength of the laser in a non-refrigerated working state is realized through a manner of real-time monitoring and dynamic stability. The specific solution is shown in FIG. 3. In the device package, an optical splitter is used to reflect a small part of the output light to the optical detector and is combined with the main controller of the laser to form a closed-loop feedback control system. A specific proportion of light splitting is determined by the output light intensity and the minimum light intensity required by the optical detector. The optical splitter may be a reflective light splitting sheet plated with a partially reflective film, and may also be an integrated light splitting device, such as a planar waveguide optical splitter and the like. The optical detector feeds back the detected wavelength variation to the main controller in real time, and the main controller adjusts the drive current and the SOA compensation current of the laser in the chip according to the wavelength detection result, so as to realize the wavelength output with a dynamic stability.

The continuous wavelength tuning of the laser in the entire wavelength tuning range is realized through the following method. Firstly, a unit laser covers a relatively small range of continuous wavelength tuning through a thermal effect tuning method of the drive current. The wavelength tuning range is not less than the wavelength interval Δλ of the multi-wavelength array. The wavelength tuning in this range is realized by the electrothermal tuning for the corresponding laser unit. When the required tuning range is greater than the wavelength interval, the main controller selects the laser unit with a wavelength of being closest to a new wavelength to work according to the requirement of the new wavelength, and uses the thermal effect tuning method of the drive current to fine-tune the wavelength of a new unit laser to make it match the working requirement of the new wavelength.

The output power of the laser is determined jointly by the drive current of the working unit laser and the drive current of the integrated SOA. When the thermal effect wavelength tuning of the drive current is performed, the optical amplifier also performs corresponding current adjustment to compensate for the variation of the output power caused by the variation of the drive current, so as to realize that the output power is basically unchanged when the wavelength tuning is performed. The specific variation amount is determined by the closed loop feedback system in FIG. 1. Similar to the wavelength stabilization method, the optical splitter is also used to reflect a small part of the output light to the optical detector for detection, and the power detection result is input to the main controller. When the increase in power is detected, the main controller increases the working current of the SOA, otherwise, the main controller reduces the working current of the SOA. In this way, the fluctuation of the output power of the laser during the wavelength tuning is suppressed to realize dynamic stability of the output power.

In some examples, since the specific proportion of light splitting of the optical splitter is determined by the output light intensity and the minimum light intensity required by the optical detector, the optical splitter can also be used as an auxiliary power adjusting device to provide a part of output power adjusting function to reduce the difficulties of adjusting and controlling under special situations.

Referring to FIG. 3, the present invention also provides a working method of a non-refrigerated tunable semiconductor laser based on a multi-wavelength array, and the working method includes the following steps.

S1: the external environment temperature, the characteristics of the wavelength and the power of the actual output light are collected in real time.

S2: the difference between the wavelength of the actual output light and the theoretical wavelength is calculated; if the difference is greater than the tunable range of the current laser unit in a working state, go to step S3, otherwise, go to step S4.

S3: the corrected wavelength value after compensation for wavelength drift is calculated, and the drive current of the tunable laser array is initially adjusted to drive a laser unit with a wavelength of being closest to the corrected wavelength value to emit a laser beam.

S4: in conjunction with the difference between the fed-back wavelength value of the actual output light and the theoretical wavelength, the thermal effect tuning method of the drive current is used to fine-tune the drive current of the tunable laser array to enable the fed-back wavelength value of the actual output light to be consistent with the theoretical wavelength.

S5: in conjunction with the fed-back power value of the actual output light and the theoretical power, the drive current of the optical amplifier is fine-tuned to enable the fed-back power value of the actual output light to be consistent with the theoretical power.

(IV) Multiplexing Structure

Referring to FIGS. 2A-2H, it can be seen that the multiplexing structure includes a passive multiplexing structure and an active multiplexing structure. The passive multiplexing structure includes a multimode interferometer structure, a cascaded Y-branch waveguide structure or an arrayed waveguide grating structure. The active multiplexing structure includes a cascaded Y-branch waveguide structure.

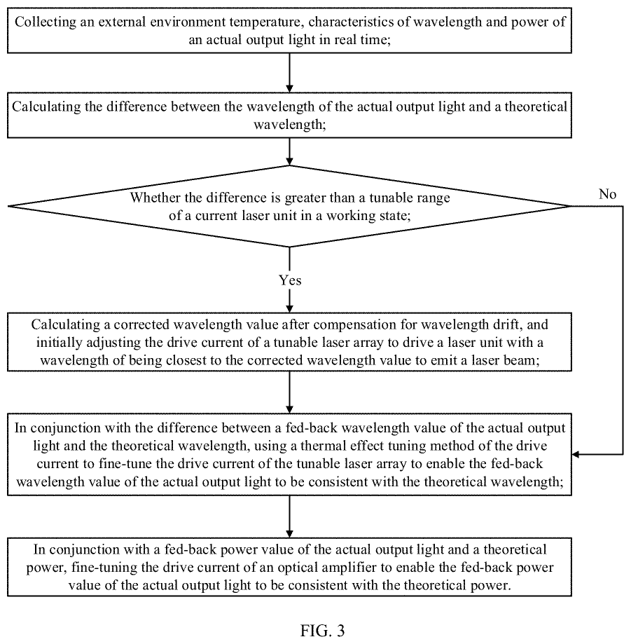

Referring to FIG. 4, the present invention proposes a preparation method of a non-refrigerated tunable semiconductor laser based on a multi-wavelength array, and the preparation method includes the following steps.

S100: a tunable laser array is prepared. The tunable laser array is an array-type distributed feedback semiconductor laser chip based on the reconstruction-equivalent-chirp technology, includes a plurality of laser units with different wavelengths. One of the laser units is driven to emit a laser beam with a corresponding wavelength according to a control instruction of the main controller.

S200: a thermistor and the prepared tunable laser array are bonded to a heat sink substrate configured as a carrier by welding or gluing. An angle for suppressing the F-P cavity effect is formed between a light outputting end face of the tunable laser array and an upper surface of the heat sink substrate. In the device, the materials with lower thermal conductivity are used as the carrier of the laser chip during the package to enhance the thermal effect of the drive current and realize the tuning of the wavelength of the distributed feedback semiconductor laser in a relatively large range by using the thermal effect of the drive current of the laser. The thermal tuning range is greater than the wavelength interval of the array, so as to realize the continuous tuning of the wavelength in the entire working range.

S300: a passive multiplexing structure is integrated at an output end of the tunable laser array through photonic wire bonding technology, or an active multiplexing structure is monolithically integrated at the output end of the tunable laser array through material growth, so as to realize a single-port light outputting function of the tunable laser array.

S400: a semiconductor optical amplifier is integrated at the end of the passive multiplexing structure, or the end of the active multiplexing structure, and amplifying or attenuating a power of the final output light by changing the input current of the optical amplifier.

S500: the end of the optical amplifier is coupled with an optical fiber by packaging an isolator microlens assembly at end of the optical amplifier or using the photonic wire bonding technology to enable the laser light emitted by the laser chip to be output through the optical fiber.

As shown in FIG. 2B, a passive multiplexing structure is monolithically integrated with the laser chip through material growth. The passive multiplexing structure may be a multimode interferometer structure, a cascaded Y-branch waveguide structure or an arrayed waveguide grating structure. The single-port light outputting function can be realized through the passive multiplexing structure.

As shown in FIG. 2C, a passive multiplexing structure is integrated with the laser chip through the photonic wire bonding technology. The passive multiplexing structure may be a multimode interferometer structure, a cascaded Y-branch waveguide structure or an arrayed waveguide grating structure. The single-port light outputting function can be realized through the passive multiplexing structure.

As shown in FIG. 2D, a passive multiplexing structure is integrated with the laser chip through the photonic wire bonding technology, and a semiconductor optical amplifier structure is integrated at the end of the passive multiplexing structure. The passive multiplexing structure may be a multimode interferometer structure, a cascaded Y-branch waveguide structure or an arrayed waveguide grating structure. The single-port light outputting function can be realized through the passive multiplexing structure, and the power of the final output light can be amplified or attenuated by changing the input current of the optical amplifier.

As shown in FIG. 2E, an active multiplexing structure is monolithically integrated with the laser chip through material growth. The active multiplexing structure is generally a cascaded Y-branch waveguide structure. The multiplexing single-port light outputting function can be realized by applying current to the active multiplexing structure.

As shown in FIG. 2F, an active multiplexing structure is monolithically integrated with the laser chip through material growth, and a semiconductor optical amplifier structure is integrated at the end of the active multiplexing structure. The active multiplexing structure is generally a cascaded Y-branch waveguide structure. The multiplexing single-port light outputting function can be realized by applying current to the active multiplexing structure, and the power of the final output light can be amplified or attenuated by changing the input current of the optical amplifier.

As shown in FIG. 2G, the laser chip is an array-type distributed feedback semiconductor laser chip based on the reconstruction-equivalent-chirp technology. The laser chip and a thermistor are together bonded to a heat sink substrate by welding or gluing, and the end of the laser chip is coupled with an optical fiber by packaging an isolator microlens assembly, so that the laser light emitted by the laser chip can be output through the optical fiber.

As shown in FIG. 2H, the laser chip is an array-type distributed feedback semiconductor laser chip based on the reconstruction-equivalent-chirp technology. The laser chip and a thermistor are together bonded to a heat sink substrate by welding or gluing, and the end of the laser chip is coupled with an optical fiber through the photonic wire bonding technology, so that the laser light emitted by the laser chip can be output through the optical fiber.

In this disclosure, various aspects of the present invention are described with reference to the drawings, and many illustrated embodiments are shown in the drawings. The embodiments of the present disclosure are not necessarily defined to include all aspects of the present invention. It should be understood that the various concepts and embodiments introduced above, as well as those described in more detail below, can be implemented in any of many manners, because the concepts and embodiments disclosed in the present invention are not limited to any implementation. In addition, some aspects disclosed in the present invention can be used alone or in any appropriate combination with other aspects disclosed in the present invention.

The present invention has been disclosed as above through preferred embodiments, but the preferred embodiments are not used to limit the present invention. Various changes and modifications may be made by those having ordinary skill in the art without departing from the spirit and scope of the present invention, but the scope of protection of the present invention should be subject to what is defined in the claims.

What is claimed is:

1. A non-refrigerated tunable semiconductor laser based on a multi-wavelength array, comprising a thermistor, a tunable laser array, a multiplexing structure, an optical amplifier, an optical splitter, an optical detector, and a main controller; wherein
the tunable laser array comprises a plurality of laser units with different wavelengths, and the tunable laser array is connected to the optical splitter and the main controller through the multiplexing structure and the optical amplifier in sequence;
one of the plurality of laser units is driven to emit a laser beam with a corresponding wavelength according to a control instruction of the main controller, and the laser beam is amplified by the optical amplifier and then enters the optical splitter;
the optical splitter is provided with two output ends, wherein a first output end of the two output ends is set as a light outputting end, and a second output end of the two output ends is connected to the main controller through the optical detector to constitute a feedback loop, wherein the feedback loop feeds back characteristics of a wavelength and a power of an actual output light to the main controller in real time;
the thermistor is connected to the main controller to detect an external environment temperature in real time and feed back a detection result to the main controller; and
the main controller calculates a corrected wavelength value after a compensation for a wavelength drift in conjunction with a set theoretical wavelength and the external environment temperature detected in real time, and the main controller initially adjusts a drive current of the tunable laser array to drive a laser unit with a wavelength of being closest to the corrected wavelength value to emit the laser beam; then, according to the fed-back characteristics of the wavelength and the power of the actual output light, the main controller fine-tunes the drive current of the tunable laser array and a drive current of the optical amplifier in conjunction with the set theoretical wavelength and a theoretical power to enable the actual output light to satisfy requirements of the set theoretical wavelength and the theoretical power.

2. The non-refrigerated tunable semiconductor laser based on the multi-wavelength array of claim 1, further comprising a heat sink substrate, wherein the heat sink substrate is configured as a carrier of the thermistor, the tunable laser array, the multiplexing structure and the optical amplifier.

3. The non-refrigerated tunable semiconductor laser based on the multi-wavelength array of claim 1, wherein the multiplexing structure comprises a passive multiplexing structure and an active multiplexing structure;
the passive multiplexing structure comprises a multimode interferometer structure, a cascaded Y-branch waveguide structure or an arrayed waveguide grating structure; and
the active multiplexing structure comprises the cascaded Y-branch waveguide structure.

4. The non-refrigerated tunable semiconductor laser based on the multi-wavelength array of claim 1, wherein a maximum tuning wavelength range of the tunable laser array satisfies:
the maximum tuning wavelength range=a theoretical tuning wavelength range+an additional tuning wavelength range;
wherein the additional tuning wavelength range is determined by characteristics of the wavelength drift caused by a variation of the environment temperature.

5. The non-refrigerated tunable semiconductor laser based on the multi-wavelength array of claim 1, wherein a fixed wavelength interval is disposed between the plurality of laser units;
a total number of the plurality of laser units of the tunable laser array satisfies:
the total number of the plurality of laser units=the maximum tuning wavelength range/the fixed wavelength interval.

6. The non-refrigerated tunable semiconductor laser based on the multi-wavelength array of claim 1, wherein the plurality of laser units are arranged in parallel, in series or in a matrix form.

7. The non-refrigerated tunable semiconductor laser based on the multi-wavelength array of claim 1, wherein the plurality of laser units comprise a distributed feedback (DFB) laser using a reconstruction-equivalent-chirp technology, and a waveguide structure comprises a ridge waveguide type and a buried heterostructure type;
when the waveguide structure is the ridge waveguide type, a deep etching is performed on both sides of a waveguide to confine a light; and
when the waveguide structure is the buried heterostructure type, an indium phosphide material is grown and buried on both sides of the waveguide to confine the light.

8. The non-refrigerated tunable semiconductor laser based on the multi-wavelength array of claim 1, wherein a specific proportion of the optical splitter is determined by an output light intensity and a minimum light intensity, wherein the minimum light intensity is required by the optical detector.

9. A working method of a non-refrigerated tunable semiconductor laser based on a multi-wavelength array, wherein the non-refrigerated tunable semiconductor laser employs the non-refrigerated tunable semiconductor laser based on the multi-wavelength array of claim 1;
the working method comprises:
S1: collecting the external environment temperature, the characteristics of the wavelength and the power of the actual output light in real time;
S2: calculating a difference between the wavelength of the actual output light and the set theoretical wavelength; when the difference is greater than a tunable range of a current laser unit in a working state, going to step S3, otherwise, going to step S4;
S3: calculating the corrected wavelength value after the compensation for the wavelength drift, and initially adjusting the drive current of the tunable laser array to drive the laser unit with the wavelength of being closest to the corrected wavelength value to emit the laser beam;
S4: in conjunction with a difference between a fed-back wavelength value of the actual output light and the set theoretical wavelength, using a thermal effect tuning method of the drive current to fine-tune the drive current of the tunable laser array to enable the fed-back wavelength value of the actual output light to be consistent with the set theoretical wavelength; and
S5: in conjunction with a fed-back power value of the actual output light and the theoretical power, fine-tuning the drive current of the optical amplifier to enable the fed-back power value of the actual output light to be consistent with the theoretical power.

10. A preparation method of a non-refrigerated tunable semiconductor laser based on a multi-wavelength array, wherein the non-refrigerated tunable semiconductor laser employs the non-refrigerated tunable semiconductor laser based on the multi-wavelength array of claim 1;
the preparation method comprises:
S100: preparing the tunable laser array; wherein the tunable laser array is an array-type distributed feedback semiconductor laser chip based on a reconstruction-equivalent-chirp technology, and the tunable laser array comprises the plurality of laser units with different wavelengths; one of the plurality of laser units is driven to emit the laser beam with the corresponding wavelength according to the control instruction of the main controller;
S200: bonding the thermistor and the tunable laser array to a heat sink substrate by welding or gluing; wherein the heat sink substrate is configured as a carrier, and an angle for suppressing an Fabry-Perot (F-P) cavity effect is formed between a light outputting end face of the tunable laser array and an upper surface of the heat sink substrate;
S300: integrating a passive multiplexing structure at an output end of the tunable laser array through a photonic wire bonding technology, or monolithically integrating an active multiplexing structure at the output end of the tunable laser array through material growth, and realizing a single-port light outputting function of the tunable laser array;
S400: integrating a semiconductor optical amplifier at an end of the passive multiplexing structure or an end of the active multiplexing structure, and amplifying or attenuating a power of a final output light by changing an input current of the semiconductor optical amplifier; and
S500: coupling an end of the semiconductor optical amplifier with an optical fiber by packaging an isolator microlens assembly at the end of the semiconductor optical amplifier or using the photonic wire bonding technology to enable a laser light emitted by the array-type distributed feedback semiconductor laser chip to be output through the optical fiber.

11. The non-refrigerated tunable semiconductor laser based on the multi-wavelength array of claim 2, wherein a fixed wavelength interval is disposed between the plurality of laser units;
a total number of the plurality of laser units of the tunable laser array satisfies:
the total number of the plurality of laser units=the maximum tuning wavelength range/the fixed wavelength interval.

12. The non-refrigerated tunable semiconductor laser based on the multi-wavelength array of claim 3, wherein a fixed wavelength interval is disposed between the plurality of laser units;
a total number of the plurality of laser units of the tunable laser array satisfies:
the total number of the plurality of laser units=the maximum tuning wavelength range/the fixed wavelength interval.

13. The non-refrigerated tunable semiconductor laser based on the multi-wavelength array of claim 4, wherein a fixed wavelength interval is disposed between the plurality of laser units;
a total number of the plurality of laser units of the tunable laser array satisfies:
the total number of the plurality of laser units=the maximum tuning wavelength range/the fixed wavelength interval.

14. The non-refrigerated tunable semiconductor laser based on the multi-wavelength array of claim 2, wherein the plurality of laser units are arranged in parallel, in series or in a matrix form.

15. The non-refrigerated tunable semiconductor laser based on the multi-wavelength array of claim 3, wherein the plurality of laser units are arranged in parallel, in series or in a matrix form.

16. The non-refrigerated tunable semiconductor laser based on the multi-wavelength array of claim 4, wherein the plurality of laser units are arranged in parallel, in series or in a matrix form.

17. The non-refrigerated tunable semiconductor laser based on the multi-wavelength array of claim 2, wherein the plurality of laser units comprise a distributed feedback (DFB) laser using a reconstruction-equivalent-chirp technology, and a waveguide structure comprises a ridge waveguide type and a buried heterostructure type;
when the waveguide structure is the ridge waveguide type, a deep etching is performed on both sides of a waveguide to confine a light; and
when the waveguide structure is the buried heterostructure type, an indium phosphide material is grown and buried on both sides of the waveguide to confine the light.

18. The non-refrigerated tunable semiconductor laser based on the multi-wavelength array of claim 3, wherein the plurality of laser units comprise a distributed feedback (DFB) laser using a reconstruction-equivalent-chirp technology, and a waveguide structure comprises a ridge waveguide type and a buried heterostructure type;
when the waveguide structure is the ridge waveguide type, a deep etching is performed on both sides of a waveguide to confine a light; and
when the waveguide structure is the buried heterostructure type, an indium phosphide material is grown and buried on both sides of the waveguide to confine the light.

19. The non-refrigerated tunable semiconductor laser based on the multi-wavelength array of claim 4, wherein the plurality of laser units comprise a distributed feedback (DFB) laser using a reconstruction-equivalent-chirp technology, and a waveguide structure comprises a ridge waveguide type and a buried heterostructure type;
when the waveguide structure is the ridge waveguide type, a deep etching is performed on both sides of a waveguide to confine a light; and
when the waveguide structure is the buried heterostructure type, an indium phosphide material is grown and buried on both sides of the waveguide to confine the light.

20. The non-refrigerated tunable semiconductor laser based on the multi-wavelength array of claim 2, wherein a specific proportion of the optical splitter is determined by an output light intensity and a minimum light intensity, wherein the minimum light intensity is required by the optical detector.
